(19) United States
(12) Patent Application Publication
(10) Pub. No.: US 2021/0211115 A1
(43) Pub. Date: Jul. 8, 2021

(54) PIEZOELECTRIC RESONATOR AND MANUFACTURING METHOD OF PIEZOELECTRIC RESONATOR

(71) Applicant: ANHUI YUNTA ELECTRONIC TECHNOLOGIES CO., LTD., Ningguo (CN)

(72) Inventors: Chengjie ZUO, Ningguo (CN); Jun HE, Ningguo (CN)

(73) Assignee: ANHUI YUNTA ELECTRONIC TECHNOLOGIES CO., LTD., Ningguo (CN)

(21) Appl. No.: 16/754,169

(22) PCT Filed: May 2, 2018
(86) PCT No.: PCT/CN2018/085289

§ 371 Date: Apr. 7, 2020

(30) Foreign Application Priority Data
Nov. 14, 2017 (CN) 201711121168.8
Nov. 14, 2017 (CN) 201721512611.X

(51) Int. Cl. H03H 9/17; H03H 3/04; H03H 9/02; H03H 9/13

(52) U.S. Cl. CPC H03H 9/173; H03H 3/04; H03H 2003/021; H03H 9/132; H03H 9/02102

(57) ABSTRACT

Provided are a piezoelectric resonator and a manufacturing method of the piezoelectric resonator. The piezoelectric resonator includes a substrate, a recess is formed on an upper surface of the substrate; a first piezoelectricity layer covering the upper surface of the substrate and an opening of the recess to enable the recess and the first piezoelectricity layer to form a cavity; a first electrode and a temperature compensation layer, which are both disposed on a side of the first piezoelectricity layer facing away from the substrate, in a direction perpendicular to the substrate, a projection of the first electrode on the substrate is located at an area in which the recess is located.

### TECHNICAL FIELD

The present disclosure relates to a technical field of acoustic wave resonators, for example, to a piezoelectric resonator and a manufacturing method of the piezoelectric resonator.

### BACKGROUND

Surface acoustic wave devices (such as surface acoustic wave (SAW filter) are circuit components that convert electrical signals into surface waves and perform the signal processing, and are widely used as filters, resonators and the like. The quality factor (Q) and the temperature coefficient of frequency (TCF) enable the surface acoustic wave devices to have important significance in the research and development of electronic components such as piezoelectric resonators.

FIG. 1 is a sectional view of a structure of a piezoelectric resonator in the existing art. As shown in FIG. 1, the piezoelectric resonator (such as a SAW resonator) includes a substrate 1, a high acoustic velocity layer 2 (an aluminum nitride material) located on an upper surface of the substrate 1, a low acoustic velocity layer 3 located at a surface of a side of the high acoustic velocity layer 2 facing away from the substrate 1, a piezoelectric layer 4 (lithium tantalite) located at a surface of a side of the low acoustic velocity layer 3 facing away from the high acoustic velocity layer 2 and an electrode 5 located at a surface of a side of the piezoelectric layer 4 facing away from the low acoustic velocity layer 3. Since there exists an acoustic mismatch between the low acoustic velocity layer 3 and the high acoustic velocity layer 2, acoustic waves of the boundary face between the low acoustic velocity layer 3 and the high acoustic velocity layer 2 reflect. Thus, leakage of acoustic wave energy can be reduced. However, such structure enables longitudinal acoustic waves to leak into the substrate 1 through the high acoustic velocity layer 2, increases the acoustic wave energy loss in the substrate and results in reduction of the Q value of the piezoelectric resonator.

### SUMMARY

Embodiments of the present application provide a piezoelectric resonator and a manufacturing method of the piezoelectric resonator, which effectively avoids the acoustic wave energy leaking into the substrate, reduces the acoustic wave energy loss in the substrate, and a piezoelectric resonator with a high Q value may be obtained and the obtained piezoelectric resonator has a low frequency temperature coefficient.

The embodiment of the present application provides a piezoelectric resonator. The piezoelectric resonator includes:
a substrate, a recess is formed on an upper surface of the substrate;
a first piezoelectricity layer, covering the upper surface of the substrate and an opening of the recess to enable the recess and the first piezoelectricity layer to form a cavity;
a first electrode and a temperature compensation layer, which are both disposed on a side facing away from the first piezoelectricity layer, in a direction perpendicular to the substrate, a projection of the first electrode on the substrate is located at an area in which the recess is located.

The embodiment of the present application further provides a manufacturing method of a piezoelectric resonator. The method includes:
forming a recess on an upper surface of the substrate;
filling a sacrificial material in the recess, wherein an upper surface of the sacrificial material is flush with the upper surface of the substrate;
covering the upper surface of the substrate and the upper surface of the sacrificial material by a first piezoelectricity layer;
forming a first electrode and a temperature compensation layer on a side of the first piezoelectricity layer facing away from the substrate, wherein in a direction perpendicular to the substrate, the first electrode is located at an area in which the recess is located;
removing the sacrificial material to form a cavity.

In solutions provided by embodiments of the present application, through forming the recess on the upper surface of the substrate, a cavity is formed between the recess and the first piezoelectric layer, so that the acoustic waves form a total reflection through the cavity layer, which may effectively avoid the acoustic wave energy leaking into the substrate, reduce the acoustic wave energy loss in the substrate and obtain a piezoelectric resonator with a high Q value. Meanwhile, the disposed temperature compensation layer may enable the piezoelectric resonator to maintain a low frequency temperature coefficient and effectively improve the temperature compensation efficiency. When the second electrode is provided in the cavity, through mutual action of the second electrode and the first electrode, the application scope of the piezoelectric resonator may be expanded; meanwhile, the volume of the piezoelectric resonator manufactured on the sealed cavity may be smaller.

### BRIEF DESCRIPTION OF DRAWINGS

FIG. 1 is a sectional view of a structure of a piezoelectric resonator in the existing art;

FIG. 2 is a sectional view of a structure of a piezoelectric resonator provided by an embodiment;

FIG. 3 is a sectional view of a structure of another piezoelectric resonator provided by an embodiment;

FIG. 4 is a sectional view of a structure of another piezoelectric resonator provided by an embodiment;

FIG. 5 is a sectional view of a structure of another piezoelectric resonator provided by an embodiment;

FIG. 6 is a sectional view of a structure of another piezoelectric resonator provided by an embodiment;

FIG. 7 is a sectional view of a structure of another piezoelectric resonator provided by an embodiment;

FIG. 8 is a sectional view of a structure of another piezoelectric resonator provided by an embodiment;

FIG. 9 is a sectional view of a structure of another piezoelectric resonator provided by an embodiment; and

FIG. 10 is a flowchart of a piezoelectric method of a piezoelectric resonator provided by an embodiment.

### DETAILED DESCRIPTION

The present application will be further described with reference to the accompanying drawings and embodiments. It is to be understood that the embodiments set forth below are intended to illustrate and not to limit the present disclosure. It is to be noted that to facilitate description, only part, not all, of structures related to the present application are illustrated in the accompanying drawings.

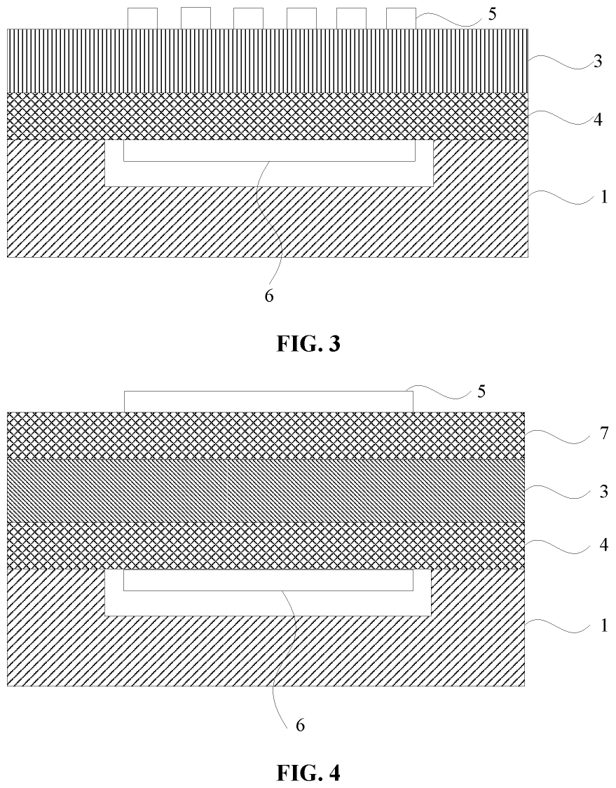

The embodiment of the present application provides a piezoelectric resonator. The device is applicable to a field of communications. FIG. 2 is a sectional view of a structure of a piezoelectric resonator provided by an embodiment of the present application. Referring to FIG. 2, a structure of the piezoelectric resonator includes a substrate 1, a first piezoelectricity layer 4, a first electrode 5 and a temperature compensation layer 3 which are sequentially disposed. A recess 11 is formed on the upper surface of the substrate 1. The first piezoelectricity layer 4 is covered on the upper surface of the substrate and an opening of the recess 11 to enable the recess and the first piezoelectricity layer 4 to form a cavity. A section structure of the recess 11 may be a rectangle or an arc, but its shape is not limited to the rectangle or the arc, as long as the acoustic wave energy may be avoided being leaked into the substrate as much as possible. The first electrode 5 and the temperature compensation layer 3 are both disposed on a side of the first piezoelectric layer 4 facing away from the substrate 1, and in a direction perpendicular to the substrate 1, a projection of the first electrode 5 on the substrate 1 is located in the area in which the substrate 11 is located, where the first electrode 5 disposed on the side of the first piezoelectric layer 4 facing away from the substrate 1 may be on an upper surface of the temperature compensation layer 3, or the first electrode 5 disposed on the side of the first piezoelectric layer 4 facing away from the substrate 1 may be disposed on a same layer with the temperature compensation layer 3.

In solutions of the present application, through forming the recess on the upper surface of the substrate, a cavity is formed between the recess and the first piezoelectric layer, which may effectively avoid that the acoustic wave energy leaks into the substrate, reduce the acoustic wave energy loss in the substrate and obtain a piezoelectric resonator with a high Q value. Meanwhile, the disposed temperature compensation layer may enable the piezoelectric resonator to maintain a low temperature coefficient of frequency and effectively improve the temperature compensation efficiency.

In one embodiment, the first electrode is located at a surface of the first piezoelectric layer facing away from the substrate, and the temperature compensation layer covers the first electrode.

As shown in FIG. 2, the piezoelectric resonator includes the substrate 1, the first electrode 5, the first piezoelectric layer 4 and the temperature compensation layer 3. The material of the substrate may be silicon, and may be a high acoustic velocity support substrate. An electrical resistivity of the substrate is about 1000 Ω·cm or more. When the piezoelectric resonator is used as a filter, an insertion loss of the filter may be reduced. The first piezoelectric layer 4 covers the substrate 1 provided with the recess 11 to obtain a cavity structure, the first electrode 5 is located at the upper surface of the side of first piezoelectric layer 4 facing away from the substrate 1, and enables the temperature compensation layer 3 to cover the first electrode 5. The first electrodes 5 may be interdigital electrodes and distributed uniformly on the upper surface of the first piezoelectric layer 4, in this case, the material of the temperature compensation layer 3 is filled in two adjacent electrodes of the interdigital electrodes. The interdigital electrodes may stimulate different sound waves in multiple modes.

The first piezoelectric layer 4 may be aluminum nitride (AlN), zinc oxide (ZnO), lithium niobate (LiNbO₃) or lithium tantalate (LiTaO₃), etc. The first piezoelectric layer 4 is generally a negative temperature coefficient material, i.e., with increasing of the temperature, the sound velocity is reduced because the reduction of an across-atomic-force of the material causes the reduction of a material elastic constant, thereby reducing the sound velocity. The material of the temperature compensation layer may be a positive temperature coefficient material, such as SiO₂. SiO₂ is a unique material, a silicon-oxygen chain of the material stretches with the temperature rising, so that a rigidity of the material has a positive temperature coefficient, and the sound velocity of the sound waves propagated in the SiO₂ presents the positive temperature coefficient. Therefore, SiO₂ is used for compensating a frequency shift of the piezoelectric resonator caused by the temperature change, and the first piezoelectric layer 4 can implement better temperature compensation. In addition, SiO₂ may be a low sound velocity layer, and a thickness of the layer may be a nanoscale and has less influence on a Q and electromechanical coupling coefficient (Kₜ²) of the resonator.

In one embodiment, the temperature compensation layer is located at the surface of the side of the first piezoelectric layer facing away from the substrate, and the first electrode is located at a side of the temperature compensation layer facing away from the substrate. In one embodiment, the first electrode is located at a surface of the side of the temperature compensation layer facing away from the substrate. In one embodiment, the piezoelectric resonator may also include a second piezoelectricity layer located between the temperature compensation layer and the first electrode, and the first electrode is located at a surface of a side of the second piezoelectricity layer facing away from the substrate.

As shown in FIG. 3, a piezoelectric resonator includes a substrate 1, a first electrode 5, a first piezoelectricity layer 4 and a temperature compensation layer 3. The first electrode 5 is located at a side of the temperature compensation layer 3 facing away from the substrate 1. The first electrode 5 is located at an upper surface of a side of the temperature compensation layer 3 facing away from the substrate 1.

The first electrodes 5 may be interdigital electrodes and distributed uniformly on the upper surface of the temperature compensation layer 3. The first electrode 5 and the temperature compensation layer 3 are alternately disposed. The material of the interdigital electrode may be made of metal alloy such as Al or AlCu, and the interdigital electrode has the function of converting electric signals into acoustic signals through an interdigital transducer. In addition, an electrode film thickness of the interdigital electrode is about 50 nm-200 nm, which may ensure a smaller electrical resistivity of the electrode. The interdigital electrodes form an electric field in the temperature compensation layer 3 and the first piezoelectricity layer 4, thereby stimulating or acquiring acoustic waves of the filter and the resonator in a specific vibration mode.

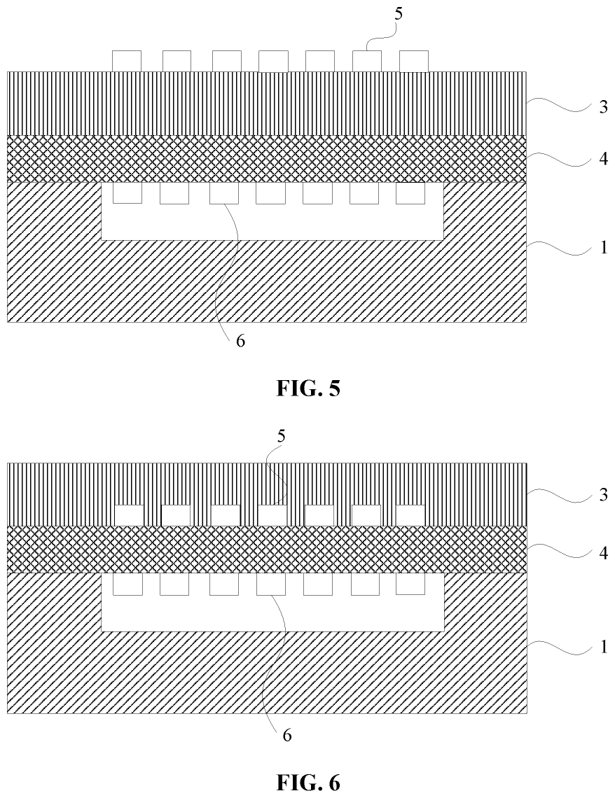

Alternatively, as shown in FIG. 4, a piezoelectric resonator includes a substrate 1, a first electrode 5, a first piezoelectricity layer 4, a temperature compensation layer 3 and a second piezoelectricity layer 7 located between the temperature compensation layer 3 and the first electrode 5. The first electrode 5 is located at a surface of a side of the second piezoelectricity layer 7 facing away from the substrate 1. Since the first piezoelectricity layer 4 and the second piezoelectricity layer 7 are generally a negative temperature coefficient material, and the temperature compensation layer 3 may be SiO2. Through mechanical calculation, it is found that in the specific vibration mode, on the assumption that the temperature compensation layer 3 is located in the middle of a piezoelectric resonator structure, the temperature compensation efficiency may reach a high value. Since the temperature coefficient of frequency (TCF) of a piezoelectric resonator is determined by the thickness of each layer structure and a relative position and function thereof in a cavity, generally, to obtain a low TCF, a thicker layer of SiO₂ needs to be deposited above or below the piezoelectric resonator to compensate for drift quantity of a resonant frequency of the piezoelectric resonator changed with the temperature. The piezoelectric resonator of the embodiment may implement the temperature compensation through manufacturing a thinner temperature compensation layer (SiO₂), greatly improving the temperature compensation efficiency.

In one embodiment, the piezoelectric resonator may also include a second electrode, the second electrode is located in the cavity and disposed at a surface of a side of the first piezoelectricity layer close to the substrate.

Exemplarily, referring to FIG. 3, the piezoelectric resonator may also include a second electrode 6, the second electrode 6 is located in the cavity and disposed at the surface of the side of the first piezoelectricity layer 4 close to the substrate 1. The first electrode 5 may be an interdigital electrode, and the second electrode 6 may be a surface electrode. Through interaction of the interdigital electrode and the surface electrode, a transverse body wave in the first piezoelectricity layer 4 and the temperature compensation layer 3 is stimulated. Because the temperature compensation layer 3 is a non-piezoelectric material SiO₂ between the first electrode 5 and the second electrode 6, the temperature compensation layer 3 consumes part of voltage of the first piezoelectric layer 4 (such as AlN), the electric field intensity of the first piezoelectric layer 4 is reduced, thus an electromechanical coupling coefficient kt2 is further reduced, and a lower effective electromechanical coupling coefficient is applicable to a narrow-band filter.

In one embodiment, the piezoelectric resonator further includes at least one of: the first electrode is an interdigital electrode or a surface electrode, and the second electrode is the interdigital electrode or the surface electrode. A shape and disposed position of at least one electrode of the first electrode and the second electrode may have various changes, and are not limited to the above situations. Through configuring the shape and position of at least one electrode of the first electrode and the second electrode, waves in different modes may be obtained, and an application scope of the piezoelectric resonator is extended.

As shown in FIG. 5, the second electrode 6 is the interdigital electrode and disposed at the surface of the side of the first piezoelectric layer 4 close to the substrate 1. In this mode, the first electrode 5 may be the interdigital electrode and located at an upper surface of the temperature compensation layer 3 facing away from the substrate 1.

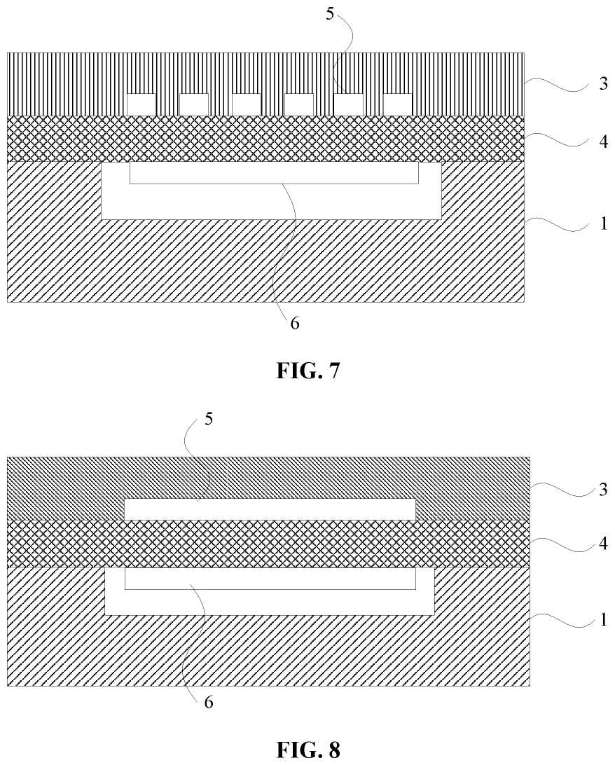

In one embodiment, as shown in FIG. 6, the second electrode 6 is the interdigital electrode and disposed at the surface of the side of the first piezoelectric layer 4 close to the substrate 1. In this mode, the first electrode 5 may be the interdigital electrode and located at the surface of the first piezoelectric layer 4 facing away from the substrate 1, and the temperature compensation layer 3 covers the first electrode 5.

The interdigital electrode may convert an electric signal into an acoustic signal, the first electrode 5 and the second electrode 6 are both interdigital electrodes, and the first electrode 5 and the second electrode 6 cooperate with each other, so that the piezoelectric resonator may be stimulated to generate a transverse body wave, a longitudinal body wave or acoustic waves in other forms according to different circuit connection modes, the transverse body wave is applicable to a narrow-band filter.

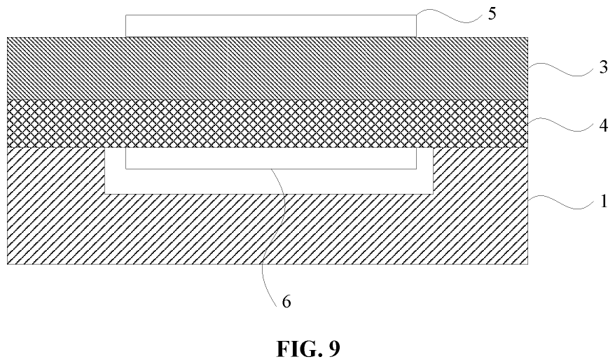

In one embodiment, as shown in FIG. 7, the second electrode 6 is the surface electrode and disposed at the surface of the side of the first piezoelectric layer 4 close to the substrate 1. In this mode, the first electrode 5 may be the interdigital electrode and located at the surface of the first piezoelectric layer 4 facing away from the substrate 1, and the temperature compensation layer 3 covers the first electrode 5. The interdigital electrode may convert the electric signal into the acoustic signal, and may stimulate the transverse body wave through cooperating with the surface electrode. In one embodiment, as shown in FIG. 4, the second electrode 6 is the surface electrode and disposed at the surface of the side of the first piezoelectric layer 4 close to the substrate 1. The first electrode 5 is the surface electrode and is disposed on the upper surface of the second piezoelectric layer 7 facing away from the substrate 1, and the temperature compensation layer 3 is disposed between the first piezoelectric layer 4 and the second piezoelectric layer 7.

In one embodiment, as shown in FIG. 8, the second electrode 6 is the surface electrode and disposed at the surface of the side of the first piezoelectric layer 4 close to the substrate 1. In this mode, the first electrode 5 may be the surface electrode and located at the surface of the first piezoelectric layer 4 facing away from the substrate 1, and the temperature compensation layer 3 covers the first electrode 5. Two surface electrodes may stimulate the longitudinal body wave and may be applicable to a mobile communication system.

In one embodiment, as shown in FIG. 9, the second electrode 6 is the surface electrode and disposed at the surface of the side of the first piezoelectric layer 4 close to the substrate 1. In this mode, the first electrode 5 may be the surface electrode and located at an upper surface of the temperature compensation layer 3 facing away from the substrate 1.

Referring to FIGS. 4, 8 and 9, the first electrode 5 is the surface electrode, and the second electrode 6 is in the cavity. The second electrode 6 may be the surface electrode. The first electrode 5 and the second electrode are both the surface electrodes, and a structure constituted by the two surface electrodes with the first piezoelectric layer 4 is similar to a structure of a film bulk acoustic resonator (FBAR). It is relatively easy to control the generation of a spurious mode and reduce the influence on the Q and kt2, through configuring the surface electrodes, the longitudinal body wave may be stimulated in piezoelectric materials and be applicable to a broad-band filter.

In the structure of the piezoelectric resonator, the temperature compensation layer (SiO₂) is generally deposited above the piezoelectric resonator. It has two functions, one function is to perform temperature compensation; and secondly, the SiO₂ layer may be used as a protection layer, preventing the piezoelectric resonator from being polluted by external water vapor, particles and other substances. To have a good filter property (bandwidth), the standard thickness of the SiO₂ layer should be less than half of the thickness of the first piezoelectric layer. If a better harmonic property and a good temperature compensation property are desired, the thickness of the SiO₂ layer may also be increased by 1.5 times of the thickness of the first piezoelectric layer.

The structure of the piezoelectric resonator provided in the embodiments of the present application, the temperature compensation layer (SiO₂) is disposed above the first piezoelectric layer, so that the acoustic wave energy is mainly concentrated in the first piezoelectric layer, and a total reflection is formed at an interface of the first piezoelectric layer and the cavity, avoiding the energy leaking into the substrate. Such structure may keep the piezoelectric resonator have a high Q value and a low TCF, especially for being applied to the case described below. In a very steep roll-off area of the filter, a slight frequency shift due to the temperature change may cause the filter to fail to meet the technical indicator in the roll-off area. In addition, the structure may also be applied to a system solving mutual interference of different communication standards such as a mobile phone system of an integration satellite radio or GPS navigation.

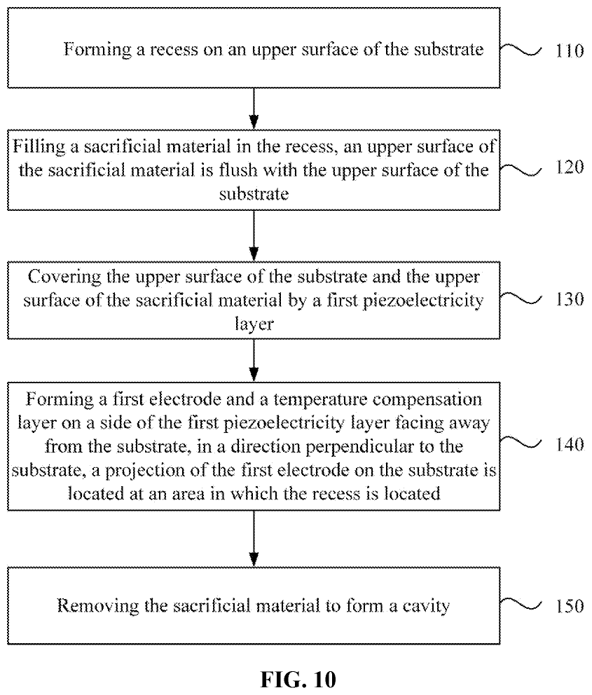

In addition, the embodiment of the present application further provides a manufacturing method of a piezoelectric resonator. FIG. 10 is a flowchart of a piezoelectric method of a piezoelectric resonator provided by an embodiment. The method includes the steps described below.

In step 110, a recess is formed on an upper surface of a substrate.

The substrate is used as a support layer, the support layer may be a silicon substrate, and on the silicon substrate, part of silicon materials may be removed through a mask or photoetching on the support layer through a deep reactive ion etching technology (DRIE). A sectional structure of the recess may be a rectangular or radial, and a depth of the sectional structure of the recess may be a nano-scale or micron-scale, a size of the recess may be selected correspondingly according to the actual demands. The silicon substrate may be a high acoustic velocity material layer, and an electrical resistivity of the substrate is about 1000 Ω·cm or more, which may reduce the insertion loss of the filter.

In step 120, a sacrificial material is filled in the recess, an upper surface of the sacrificial material is flush with the upper surface of the substrate.

In the obtained recess structure, through filling the sacrificial material, the sacrificial material may be aluminium, magnesium, SiO₂ or germanium. Through a chemical mechanical polishing (CMP) technology, a planarization process enables an upper surface of the sacrificial material to flush with an upper surface of the substrate, thereby facilitating the subsequent manufacturing of the piezoelectric layer.

In step 130, a first piezoelectricity layer is covered on the upper surface of the substrate and the upper surface of the sacrificial material.

The step in which the first piezoelectricity layer is covered on the upper surface of the substrate and the upper surface of the sacrificial material includes: forming the first piezoelectric layer by an epitaxial growth process, a film transfer process or a wafer thinning process. For example, a first piezoelectric layer of single-crystal aluminum nitride is obtained through epitaxially growing of a metal organic chemical vapor deposition method at the surface of the planarized substrate; or the single-crystal aluminum nitride manufactured on other substrates may be separated. The manufactured first piezoelectric layer of single-crystal aluminum nitride is transferred and pressed on a support layer through a film transfer process; or a wafer (such as aluminum nitride) may be bonded to a surface of the support layer by using a liquid crystal polymer (LCP) adhesive, and be bonded to a support substrate upside down, through grinding, thinning and polishing the wafer to ensure its flatness, a desired film thickness is obtained.

In step 140, a first electrode and a temperature compensation layer are formed on a side of the first piezoelectricity layer facing away from the substrate, in a direction perpendicular to the substrate, a projection of the first electrode on the substrate is located at an area in which the recess is located.

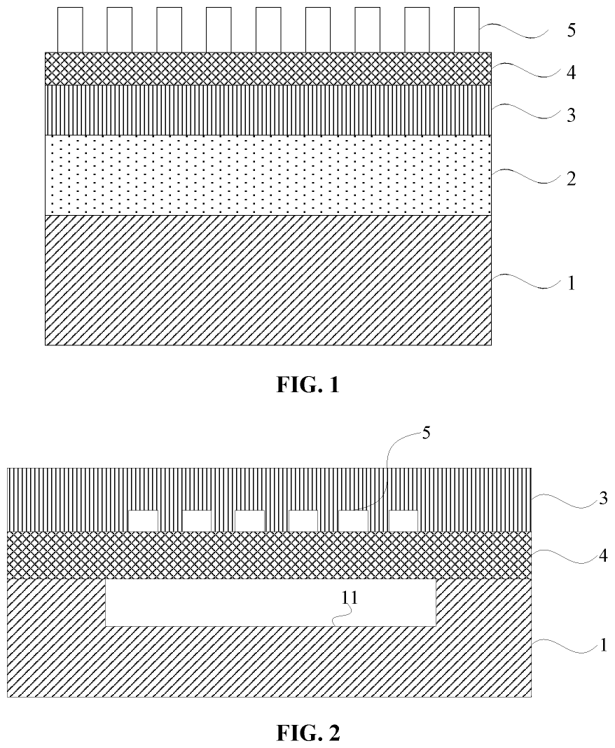

Referring to FIGS. 1 and 8, sputtering and depositing a layer of the first electrode 5 on an exposed side of the first piezoelectric layer 4 facing away from the substrate 1, the first electrode 5 may be the interdigital electrode or the surface electrode, the temperature compensation layer 3 covers the first electrode 5, the temperature compensation layer 3 may be SiO₂ material, and the interdigital electrode and the temperature compensation layer 3 are distributed in the same layer. The temperature compensation layer 3 may be used as a low acoustic velocity layer so that the acoustic wave energy is mainly concentrated in the piezoelectric material layer, thus the acoustic wave energy may be limited between the first piezoelectric layer 4 and the interdigital electrode, which may reduce the loss and improve the Q value of the piezoelectric resonator.

In addition, in a direction perpendicular to the substrate 1, the projection of the first electrode 5 on the substrate 1 is located in the area in which the recess is located. So multiple cases of the distribution position of the electrode 5 above the substrate 1, reference can be made to the embodiments of the piezoelectric resonator described above, thus will not be described herein.

In step 150, the sacrificial material is removed to form a cavity.

Referring to FIGS. 2 to 9, after manufacturing the first electrode 5 and the temperature compensation layer 3 above the first piezoelectric layer 4, along the direction perpendicular to the substrate 1, an opening is disposed at the area in which the recess is located and the sacrificial material is etched through the opening. Exemplarily, the opening may be disposed at a surface of a side of the substrate (such as a lower surface of the provided substrate 1) and the sacrificial material is etched to expose a cavity between the first piezoelectric layer 4 and the support substrate. The cavity may include air, nitrogen, etc. or the cavity may keep in a vacuum state. A second electrode 6 may be disposed in the cavity, and the second electrode 6 may be an interdigital electrodes or a surface electrode. Before the film is transferred and the wafer is pressed on the support substrate, the second electrode 6 is deposited on the surface of the side of the first piezoelectric layer 4 so that the second electrode 6 may be in the cavity. Alternatively, the second electrode 6 is deposited on the upper surface of the sacrificial material, and then the first piezoelectric layer 4 is deposited on the side of the second electrode 6 facing away from the sacrificial material. When the second electrode 6 is the interdigital electrode, a transverse body wave may be stimulated in the piezoelectric layer, so that the transverse body wave is applied to a narrow-band filter. When the second electrode 6 is a surface electrode, a longitudinal bulk wave may be stimulated, and the longitudinal bulk wave may be applied to a filter with a relatively wide bandwidth.

In solutions of the present application, through forming the recess on the upper surface of the substrate, the cavity is formed between the recess and the first piezoelectric layer, which may effectively avoid that the acoustic wave energy leaks into the substrate, reduce the acoustic wave energy loss in the substrate and obtain a piezoelectric resonator with a high Q value. Meanwhile, the disposed temperature compensation layer may enable the piezoelectric resonator to maintain a low frequency temperature coefficient and effectively improve the temperature compensation efficiency. When the second electrode is provided in the cavity, through mutual action of the second electrode and the first electrode, the application scope of the piezoelectric resonator may be expanded, and the piezoelectric resonator may be applied to the filters with a narrow bandwidth and a wide bandwidth, and the volume of the piezoelectric resonator in the embodiment is small.

### INDUSTRIAL APPLICABILITY

Embodiments of the present application provide a piezoelectric resonator and a manufacturing method of the piezoelectric resonator, which effectively avoids the acoustic wave energy leaking into the substrate, reduces the acoustic wave energy loss in the substrate, and a piezoelectric resonator with a high Q value may be obtained and the temperature compensation efficiency may be effectively improved.

1. A piezoelectric resonator, comprising: a substrate, wherein a recess is formed on an upper surface of the substrate; a first piezoelectricity layer covering the upper surface of the substrate and an opening of the recess to enable the recess and the first piezoelectricity layer to form a cavity; a first electrode and a temperature compensation layer, which are both disposed on a side of the first piezoelectricity layer facing away from the substrate, in a direction perpendicular to the substrate, a projection of the first electrode on the substrate is located at an area in which the recess is located.

2. The piezoelectric resonator of claim 1, wherein the first electrode is located at a surface of the side of the first piezoelectricity layer facing away from the substrate, the temperature compensation layer covers the first electrode.

3. The piezoelectric resonator of claim 1, wherein the temperature compensation layer is located at a surface of the side of the first piezoelectricity layer facing away from the substrate, the first electrode is located at a side of the temperature compensation layer facing away from the substrate.

4. The piezoelectric resonator of claim 3, wherein the first electrode is located at a surface of the side of the temperature compensation layer facing away from the substrate.

5. The piezoelectric resonator of claim 3, further comprising a second piezoelectricity layer located between the temperature compensation layer and the first electrode, and the first electrode is located at a surface of a side of the second piezoelectricity layer facing away from the substrate.

6. The piezoelectric resonator of claim 1, further comprising a second electrode, and the second electrode is located in the cavity and disposed at a surface of a side of the first piezoelectricity layer close to the substrate.

7. The piezoelectric resonator of claim 6, wherein
the first electrode is an interdigital electrode; or
the first electrode is a surface electrode; or
the second electrode is the interdigital electrode; or
the second electrode is the surface electrode.

8. The piezoelectric resonator of claim 1, wherein a material of the substrate is silicon.

9. The piezoelectric resonator of claim 1, wherein a material of the temperature compensation layer is a positive temperature coefficient material.

10. The piezoelectric resonator of claim 9, wherein the material of the temperature compensation layer is silica.

11. The piezoelectric resonator of claim 1, wherein a thickness of the first electrode is 100 nm-200 nm.

12. A manufacturing method of a piezoelectric resonator, comprising: forming a recess on an upper surface of the substrate; filling a sacrificial material in the recess, wherein an upper surface of the sacrificial material is flush with the upper surface of the substrate; covering the upper surface of the substrate and the upper surface of the sacrificial material by a first piezoelectricity layer; forming a first electrode and a temperature compensation layer on a side of the first piezoelectricity layer facing away from the substrate, wherein in a direction perpendicular to the substrate, a projection of the first electrode on the substrate is located at an area in which the recess is located; and removing the sacrificial material to form a cavity.

13. The manufacturing method of the piezoelectric resonator of claim 12, wherein removing the sacrificial material to form the cavity comprises: in the direction perpendicular to the substrate, providing an opening of the area in which the recess is located and etching the sacrificial material through the opening.
